(19) United States
(12) Patent Application Publication
(10) Pub. No.: US 2011/0123933 A1
(43) Pub. Date: May 26, 2011

(54) POLYMER, COMPOSITION FOR PROTECTIVE LAYER, AND PATTERNING METHOD USING THE SAME

(76) Inventors: Sang-Geun YUN, Uiwang-si (KR); Sang-Jun Choi, Uiwang-si (KR); Seung-Jib Choi, Uiwang-si (KR); Sung-Jae Lee, Uiwang-si (KR); Jin-Young Lee, Uiwang-si (KR)

(21) Appl. No.: 12/891,075

(22) Filed: Sep. 27, 2010

(30) Foreign Application Priority Data
Nov. 20, 2009 (KR) 10-2009-0112858

(51) Int. Cl. G03F 7/20; C08F 220/22; C08L 27/12

(52) U.S. Cl. 430/322; 526/245; 526/243; 524/544

(57) ABSTRACT

A polymer, including a polymerized monomer, the monomer being represented by the following Chemical Formula 1:

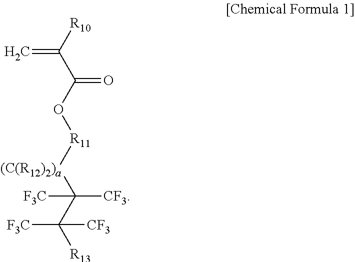

### BACKGROUND OF THE INVENTION

1. Field

Embodiments relate to a polymer, a protective layer composition, and a patterning method using the same.

2. Description of the Related Art

A finer photosensitive resin composition pattern is increasingly required for high integration of a semiconductor chip, as the semiconductor industry continues to develop. For higher integration, lithography technology that enables fine processes of a line width of about 0.1 μm or less is needed. Conventional processes, however, use near ultraviolet (UV) rays such as a g-line and an i-line, and using the near ultraviolet rays may have a limitation in performing a high-integration process of about 0.1 μm or less. Therefore, lithography technologies using ultraviolet rays having a shorter wavelength, such as far ultraviolet (UV) rays represented by the bright-line spectrum, e.g., a mercury lamp, an excimer laser, an X-ray, and an electron beam (e-beam), have been developed. Particularly, a KrF excimer laser having a wavelength of about 248 nm and an ArF excimer laser having a wavelength of about 193 nm are drawing attention.

As for the photoresist (PR) appropriate for the excimer laser exposure, researchers are studying a chemically amplified resist (CAR), which takes advantage of a chemical amplification effect caused by a component having an acid-labile functional group and an acid generating component, which generates acid upon exposure. Examples of the chemically amplified resist include a resin having a t-butyl ester group linked with a carboxylic acid or a resin having a t-butyl carbonate group linked with a phenol, and a photosensitive resin composition containing an acid generating component. The photoresist layer using the photosensitive resin composition takes an advantage of a phenomenon that a t-butyl ester group or a t-butyl carbonate group existing in the resin may be dissociated due to an action of the acid generated based on the exposure, and thus the resin comes to have an acidic group including a carboxyl group or phenolic hydroxyl group. As a result, the exposed region becomes easily soluble in an alkali development solution.

In order to form a pattern having a fine line width of less than about 45 nm, a method of making the wavelength of a light source of an exposure device short or a method of increasing the number of numerical apertures (NA) of a lens may be used. However, the method of making the wavelength of the light source short may have a drawback in terms of cost because the method additionally requires the exposure device, which is expensive. Also, the method of increasing the number of numerical apertures of a lens may have a problem in that the depth of focus (DOF) and resolution are in a trade-off relationship, such that the depth of focus is decreased when the resolution is increased.

Recently, a method called liquid immersion lithography has been developed as a technology that may overcome such problems. The liquid immersion lithography interposes a refractive index medium between the lens and the photoresist layer as a liquid for immersion exposure during the exposure. The refractive index medium may be, e.g., a fluorine-based inert liquid or pure water (n=1.44). In the liquid immersion lithography, the space of an exposure light path is filled with a liquid having a greater refractive index (n) than an inert gas such as air (n=1) or nitrogen, which is conventionally used to fill the space of the exposure light path. Thus, although a light source of the same exposure wavelength is used, the same effect may be acquired as when a light source of a short wavelength is used or a lens having many numerical apertures is used. As a result, high resolution is achieved, and at the same time, depth of focus is not deteriorated. When the liquid immersion lithography is used, it may be possible to acquire high resolution and an excellent pattern of depth of focus by using the lens mounted on a conventional device as it is.

### SUMMARY

It is a feature of an embodiment to provide a polymer, a composition for a protective layer, and a patterning method using the same.

It is another feature of an embodiment to provide a highly hydrophobic polymer with a group having high acidity.

It is another feature of an embodiment to provide a composition for a protective layer having a high receding contact angle and high solubility with respect to an alkali development solution.

It is another feature of an embodiment to provide a patterning method using the composition for a protective layer.

At least one of the above and other features and advantages may be realized by providing a polymer, including a polymerized monomer, the monomer being represented by the following Chemical Formula 1:

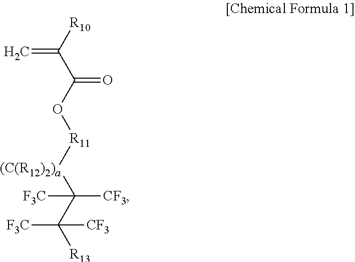

wherein, in Chemical Formula 1,

R₁₀ is selected from the group of hydrogen, fluorine, a C1 to C5 alkyl group, and a C1 to C5 fluoroalkyl group,

R₁₁ is a linear, branched, or cyclic C1 to C10 alkylene group where a part of carbon is replaced or not replaced with oxygen,

each R₁₂ is the same or different, and is selected from the group of hydrogen, a C1 to C5 alkyl group, and a C1 to C5 fluoroalkyl group,

a is an integer ranging from 0 to 10, and

R₁₃ is OH or SH.

The monomer represented by Chemical Formula 1 may be a monomer represented by the following Chemical Formula 1-1:

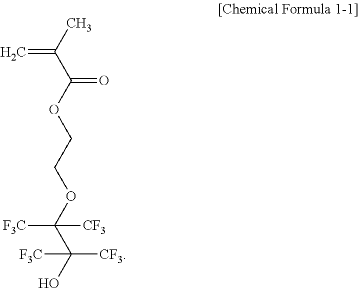

The polymer may have a weight average molecular weight of about 3,000 to about 50,000.

The polymer may be a copolymer of the monomer represented by Chemical Formula 1 and at least one monomer selected from the group of monomers represented by the following Chemical Formulae 2 to 6,

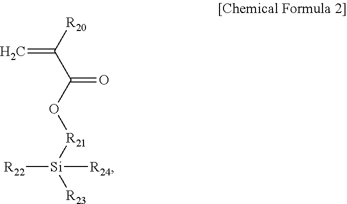

wherein, in Chemical Formula 2,

R₂₀ is selected from the group of hydrogen, fluorine, a C1 to C5 alkyl group, and a C1 to C5 fluoroalkyl group,

R₂₁ is a single bond or a linear, branched, or cyclic C1 to C10 alkylene group, and

R₂₂ to R₂₄ are the same or different, and are selected from the group of hydrogen, fluorine, a C1 to C10 alkyl group, a C1 to C10 fluoroalkyl group, and O(R₂₅),

wherein R₂₅ is selected from the group of hydrogen, fluorine, a C1 to C10 alkyl group, a C1 to C10 fluoroalkyl group, and Si(R₂₆)₃,

wherein R₂₆ is selected from the group of hydrogen, fluorine, a methyl group, and a trifluoromethyl group;

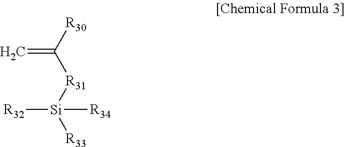

wherein, in Chemical Formula 3,

R₃₀ is selected from the group of hydrogen, fluorine, a C1 to C5 alkyl group, and a C1 to C5 fluoroalkyl group,

R₃₁ is a single bond or a linear, branched, or cyclic C1 to C10 alkylene group, and

R₃₂ to R₃₄ are the same or different, and are selected from the group of hydrogen, fluorine, a C1 to C10 alkyl group, a C1 to C10 fluoroalkyl group, and O(R₃₅),

wherein R₃₅ is selected from the group of hydrogen, fluorine, a C1 to C10 alkyl group, a C1 to C10 fluoroalkyl group, and Si(R₃₆)₃,

wherein R₃₆ is selected from the group of hydrogen, fluorine, a methyl group, and a trifluoromethyl group;

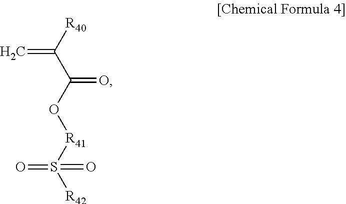

wherein, in Chemical Formula 4,

R₄₀ is selected from the group of hydrogen, fluorine, a C1 to C5 alkyl group, and a C1 to C5 fluoroalkyl group,

R₄₁ is a single bond or a linear, branched, or cyclic C1 to C10 alkylene group where a part of carbon is replaced or not replaced with nitrogen, and

R₄₂ is selected from the group of a C1 to C10 alkyl group, a C1 to C10 fluoroalkyl group and an OH group;

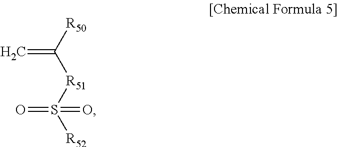

wherein, in Chemical Formula 5,

R₅₀ is selected from the group of hydrogen, fluorine, a C1 to C5 alkyl group, and a C1 to C5 fluoroalkyl group,

R₅₁ is a single bond or a linear, branched, or cyclic C1 to C10 alkylene group where a part of carbon is replaced or not replaced with nitrogen, and

R₅₂ is selected from the group of a C1 to C10 alkyl group, a C1 to C10 fluoroalkyl group, and an OH group;

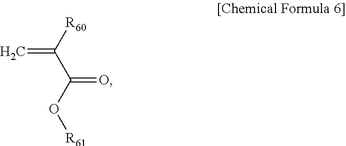

wherein, in Chemical Formula 6,

R₆₀ is selected from the group of hydrogen, fluorine, a C1 to C5 alkyl group, and a C1 to C5 fluoroalkyl group, and

R₆₁ is selected from the group of hydrogen, a C1 to C10 alkyl group, a C1 to C10 fluoroalkyl group, a C1 to C10 hydroxyalkyl group, and a C1 to C10 hydroxyalkyl group.

The polymer may be a copolymer of a monomer represented by Chemical Formula 1 and a monomer represented by Chemical Formula 2, the monomer represented by Chemical Formula 2 being selected from the group of monomers represented by the following Chemical Formulae 2-1 to 2-7:

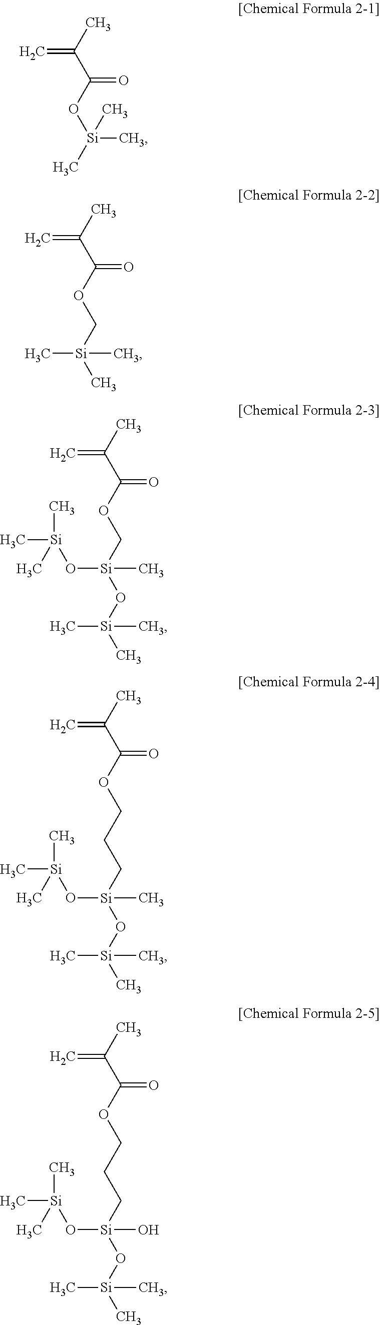

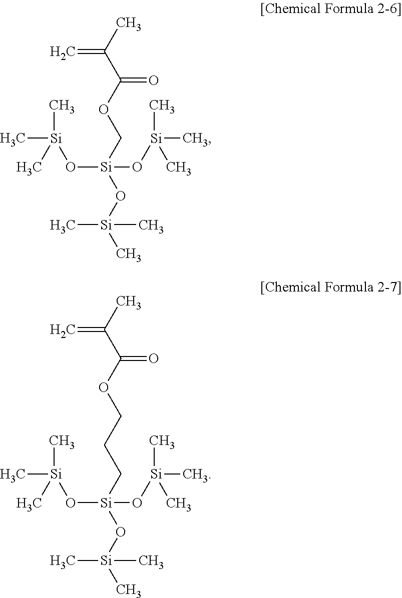

The polymer may be a copolymer of a monomer represented by Chemical Formula 1 and a monomer represented by Chemical Formula 3, the monomer represented by Chemical Formula 3 being represented by the following Chemical Formula 3-1:

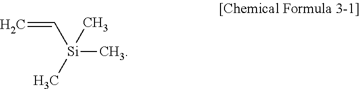

The polymer may be a copolymer of a monomer represented by Chemical Formula 1 and a monomer represented by Chemical Formula 4, the monomer represented by Chemical Formula 4 being selected from the group of monomers represented by the following Chemical Formulae 4-1 to 4-3:

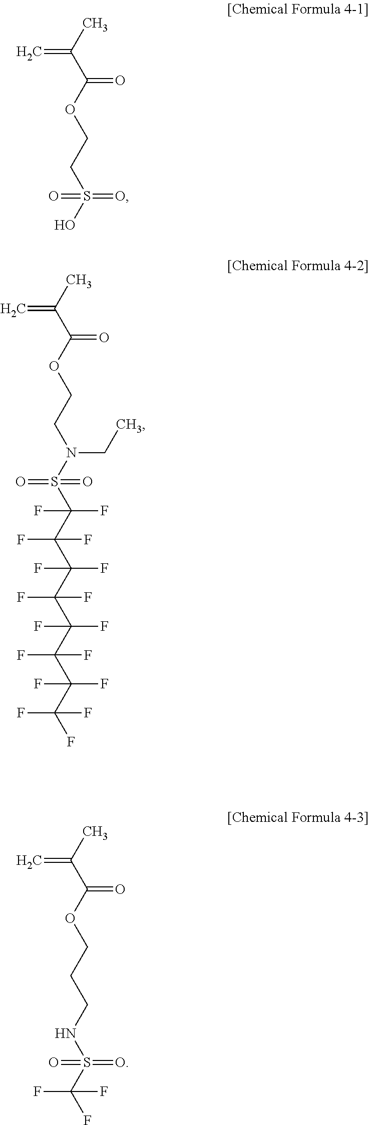

The polymer may be a copolymer of a monomer represented by Chemical Formula 1 and a monomer represented by Chemical Formula 5, the monomer represented by Chemical Formula 5 being selected from the group of monomers represented by the following Chemical Formulae 5-1 to 5-2:

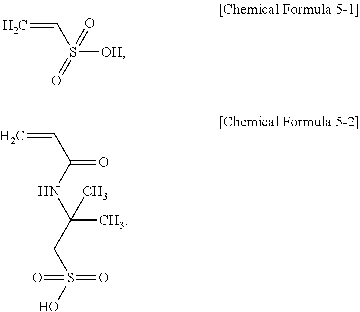

The polymer may be a copolymer of a monomer represented by Chemical Formula 1 and a monomer represented by Chemical Formula 6, the monomer represented by Chemical Formula 6 being a monomer selected from the group of monomers represented by the following Chemical Formulae 6-1 to 6-3:

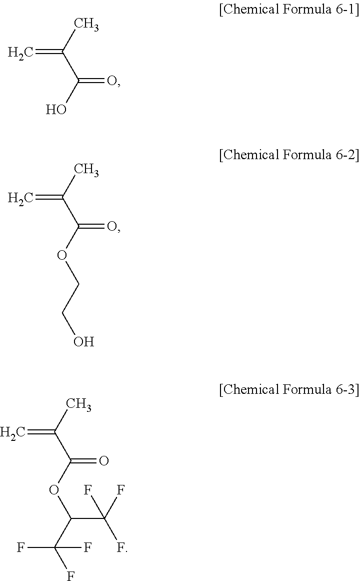

The monomers represented by the above Chemical Formulae 2 to 6 may be copolymerized in a ratio of about 1 to about 99 mol %, based on the entirety of the polymer.

At least one of the above and other features and advantages may also be realized by providing a protective layer composition, including a polymer according to an embodiment, and a solvent.

At least one of the above and other features and advantages may also be realized by providing a patterning method, including forming a photoresist layer on a substrate, forming a protective layer using a composition according to an embodiment on the photoresist layer, and forming a pattern through liquid immersion lithography using the photoresist layer having the protective layer thereon.

### BRIEF DESCRIPTION OF THE DRAWINGS

The above and other features and advantages will become more apparent to those of ordinary skill in the art by describing in detail example embodiments with reference to the attached drawings, in which:

FIG. 1 illustrates CD-SEM and FE-SEM images of after-images of a 1:1.2 line-and-space pattern formed of the protective layer composition shown in Example 6.

FIG. 2 illustrates CD-SEM images of DOF margins at 30 mJ of a pattern foamed of the protective layer composition of Example 6 through liquid immersion lithography.

FIG. 3 illustrates images of CD deviation and LWR of a pattern formed of the protective layer composition of Example 6 through liquid immersion lithography.

### DETAILED DESCRIPTION

Korean Patent Application No. 10-2009-0112858 filed on Nov. 20, 2009, in the Korean Intellectual Property Office, and entitled: “Polymer, Composition for Protective Layer, and Patterning Method Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

Herein, Markush groups, if any, are identified by the closed language “selected from the group consisting of.” Hence, the language “the group of,” as used herein, does not denote a Markush group.

A polymer according to an embodiment may be obtained by polymerizing the monomer represented by the following Chemical Formula 1.

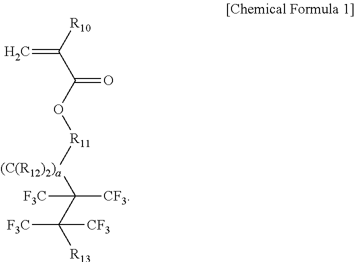

In Chemical Formula 1,

R₁₀ may be selected from the group of hydrogen, fluorine, a C1 to C5 alkyl group, and a C1 to C5 fluoroalkyl group,

R₁₁ may be a linear, branched, or cyclic C1 to C10 alkylene group where a part of carbon is replaced or not replaced with oxygen,

each R₁₂ may be the same or different, and may be selected from the group of hydrogen, a C1 to C5 alkyl group, and a C1 to C5 fluoroalkyl group,

a may be an integer ranging from 0 to 10, and

R₁₃ may be OH or SH.

Where a part of carbon is replaced or not replaced with oxygen, the moiety may be an ether (see, e.g., Formula 1-1) or an alkylene, respectively.

The monomer represented by Chemical Formula 1 may include a plurality of trifluoromethyl groups, which are electron withdrawing groups (EWG), to thereby increase the extent of the hydrophobic property and make R₁₃ coupled in the lower portion more acidic. A polymer including a repeating group derived the monomer represented by Chemical Formula 1 may be highly hydrophobic, while increasing solubility for an alkali aqueous solution by having a plurality of fluorine substituents.

In an embodiment, the polymer obtained by polymerizing the monomer represented by Chemical Formula 1 is represented by the following Chemical Formula 1A.

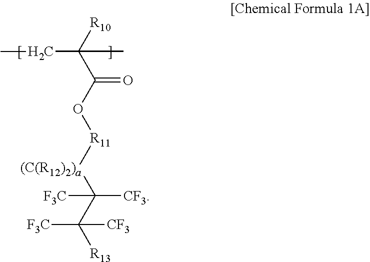

In Chemical Formula 1A, the brackets [ ] indicate a repeating unit formed by polymerization of the monomer represented by Chemical Formula 1. Further, R₁₀, R₁₁, R₁₂, a, and R₁₃ are as defined for Chemical Formula 1. As described in further detail below, the polymer represented by Chemical Formula 1A may be, e.g., a homo-polymer, a copolymer that includes moieties derived from two or more different monomers represented by Chemical Formula 1, or a copolymer that includes one or more moieties derived from monomers represented by Chemical Formula 1 and one or more monomers represented by Chemical Formulae 2 to 6.

In an embodiment, ‘a’ in Formula 1 may be an integer ranging from 1 to 10. In another embodiment, ‘a’ in Formula 1 may be an integer ranging from 0 to 10. In an embodiment, the monomer represented by Chemical Formula 1 includes a monomer represented by the following Chemical Formula 1-1.

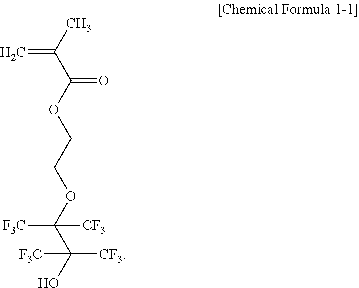

A monomer represented by Chemical Formula 1 may include both a hydrophobic group and a polar group within the molecule. A protective layer composition foamed using a polymer obtained by polymerizing the monomer alone may provide a sufficient and desirable level of water repellency and development properties. The polymer may be a homo-polymer made by polymerizing only the monomer represented by Chemical Formula 1, or it may be a copolymer including two or more monomers represented by Chemical Formula 1. Also, the polymer may be a copolymer made by copolymerizing the monomer represented by Chemical Formula 1 with at least one monomer selected from the group of the monomers represented by the following Chemical Formulae 2 to 6.

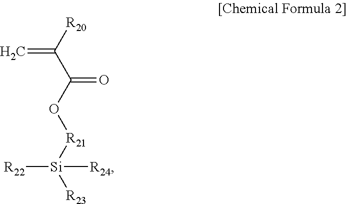

In Chemical Formula 2,

R₂₀ may be selected from the group of hydrogen, fluorine, a C1 to C5 alkyl group, and a C1 to C5 fluoroalkyl group,

R₂₁ may be a single bond or a linear, branched, or cyclic C1 to C10 alkylene group, and

R₂₂ to R₂₄ may be the same or different, and may be selected from the group of hydrogen, fluorine, a C1 to C10 alkyl group, a C1 to C10 fluoroalkyl group, and O(R₂₅),

wherein R₂₅ may be selected from the group of hydrogen, fluorine, a C1 to C10 alkyl group, a C1 to C10 fluoroalkyl group, and Si(R₂₆)₃, and

wherein R₂₆ may be selected from the group of hydrogen, fluorine, a methyl group, and a trifluoromethyl group.

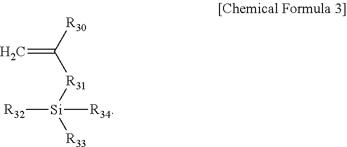

In Chemical Formula 3,

R₃₀ may be selected from the group of hydrogen, fluorine, a C1 to C5 alkyl group, and a C1 to C5 fluoroalkyl group,

R₃₁ may be a single bond or a linear, branched, or cyclic C1 to C10 alkylene group, and

R₃₂ to R₃₄ may be the same or different, and may be selected from the group of hydrogen, fluorine, a C1 to C10 alkyl group, a C1 to C10 fluoroalkyl group, and O(R₃₅),

wherein R₃₅ may be selected from the group of hydrogen, fluorine, a C1 to C10 alkyl group, a C1 to C10 fluoroalkyl group, and Si(R₃₆)₃, and

wherein R₃₆ may be selected from the group of hydrogen, fluorine, a methyl group, and a trifluoromethyl group.

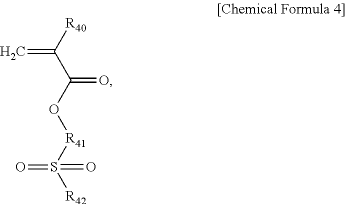

In Chemical Formula 4,

R₄₀ may be selected from the group of hydrogen, fluorine, a C1 to C5 alkyl group, and a C1 to CS fluoroalkyl group,

R₄₁ may be a single bond or a linear, branched, or cyclic C1 to C10 alkylene group where a part of carbon is replaced or not replaced with nitrogen, and

R₄₂ may be selected from the group of a C1 to C10 alkyl group, a C1 to C10 fluoroalkyl group, and an OH group.

Where part of carbon is replaced or not replaced with nitrogen, the moiety may be an aminoalkylene (see, e.g., Formulae 4-2, 4-3, below) or an alkylene, respectively.

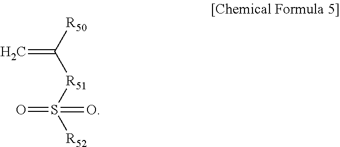

In Chemical Formula 5,

R₅₀ may be selected from the group of hydrogen, fluorine, a C1 to C5 alkyl group, and a C1 to C5 fluoroalkyl group,

R₅₁ may be a single bond or a linear, branched, or cyclic C1 to C10 alkylene group where a part of carbon is replaced or not replaced with nitrogen, and

R₅₂ may be selected from the group of a C1 to C10 alkyl group, a C1 to C10 fluoroalkyl group, and an OH group.

Where part of carbon is replaced or not replaced with nitrogen, the moiety may be an aminoalkylene (see, e.g., Formula 5-2, below) or an alkylene, respectively.

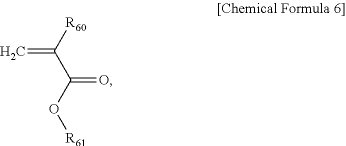

In Chemical Formula 6,

R₆₀ may be selected from the group of hydrogen, fluorine, a C1 to C5 alkyl group, and a C1 to C5 fluoroalkyl group, and

R₆₁ may be selected from the group of hydrogen, a C1 to C10 alkyl group, a C1 to C10 fluoroalkyl group, a C1 to C10 hydroxyalkyl group, and a C1 to C10 hydroxyalkyl group.

Examples of the monomer represented by Chemical Formula 2 include monomers represented by the following Chemical Formulae 2-1 to 2-7.

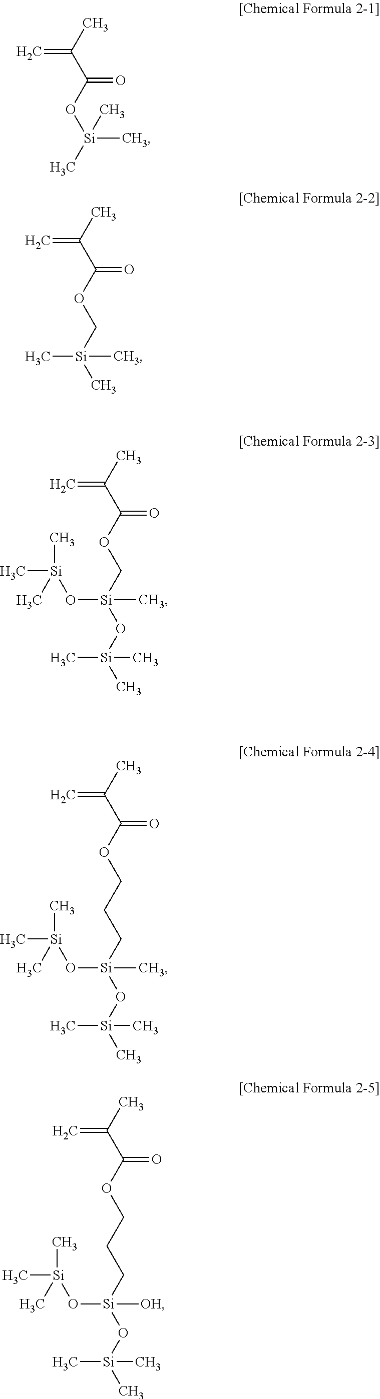

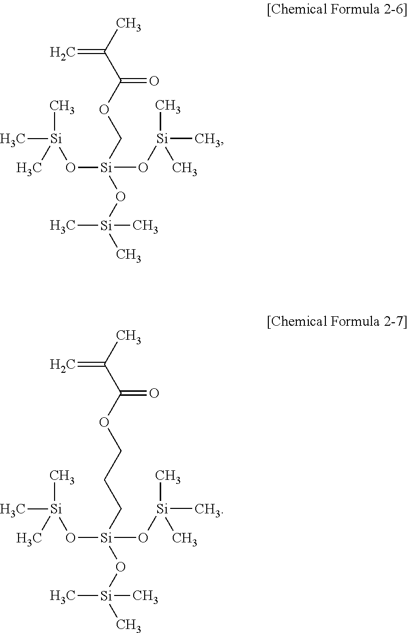

The monomer represented by Chemical Formula 3 may include a monomer represented by the following Chemical Formula 3-1.

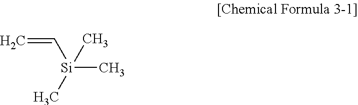

Examples of the monomer represented by Chemical Formula 4 include monomers represented by the following Chemical Formulae 4-1 to 4-3.

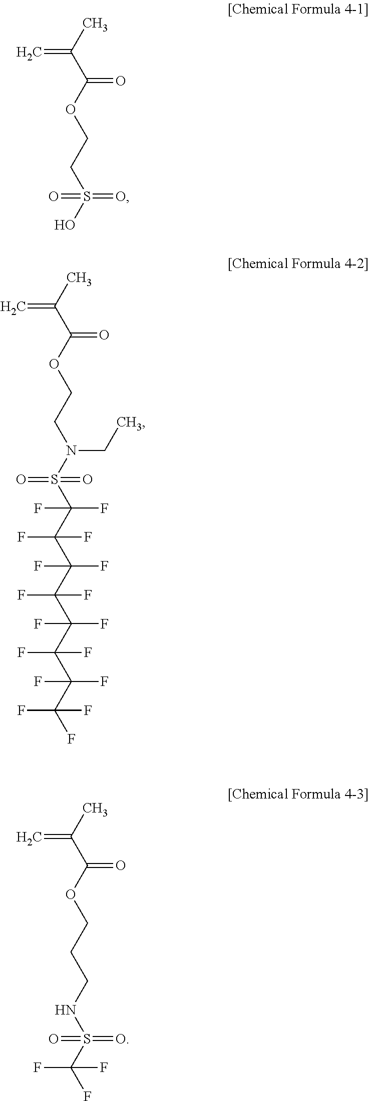

The monomer represented by Chemical Formula 5 may include monomers represented by the following Chemical Formula 5-1 to 5-2.

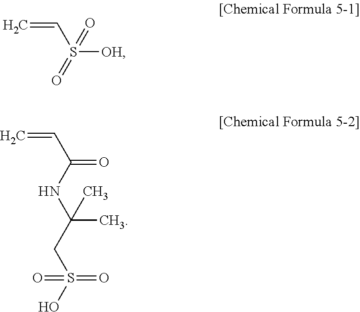

The monomer represented by Chemical Formula 6 may include monomers represented by the following Chemical Formulae 6-1 to 6-3.

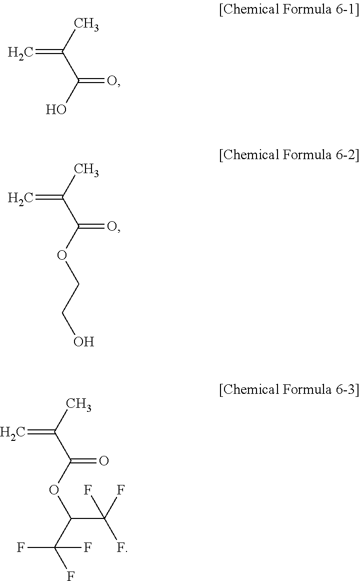

The monomers represented by the above Chemical Formulae 2 to 6 may be included in a ratio of about 1 to 99 mol % based on the entire polymer, and may be copolymerized with the monomer represented by Chemical Formula 1.

According to various embodiments, the copolymer may be, e.g., an alternating copolymer, a block copolymer, a graft copolymer, a random copolymer, etc. Further, the copolymer may be a multinary copolymer including diverse kinds of monomers such as a binary copolymer, a ternary copolymer, and the like.

The polymer may have a weight average molecular weight of about 3,000 to about 50,000, or about 4,000 to about 20,000. When the weight average molecular weight of the polymer falls in the range, the polymer may exhibit high solubility with respect to an alkali solution and a high receding contact angle with respect to water.

A protective layer composition according to an embodiment may include a solvent and the polymer according to an embodiment.

In the protective layer composition, the content of the polymer may be about 1 to about 30 parts by weight based on 100 parts by weight of the solvent. When the content of the polymer falls in the range, the protective layer may be formed by applying the resist protective layer composition in a desired coating thickness.

The solvent may have solubility with the polymer, while avoiding reaction with the polymer.

Such a solvent includes an ether-based compound, an alcohol-based compound, and the like.

Examples of the ether-based compound include di-n-butylether, diisobutylether, diisopentylether, di-n-pentylether, methylcyclopentylether, methylcyclohexylether, di-n-butylether, di-sec-butylether, diisopentylether, di-sec-pentylether, di-t-amylether, isoamylether, di-n-hexylether, and the like.

Examples of the alcohol-based compound include 1-butanol, 2-butanol, isobutanol, tert-butanol, 1-pentenol, 2-pentenol, 3-pentenol, tert-amyl alcohol, neopentanol, 2-methyl-1-butanol, 3-methyl-1-butanol, 3-methyl-3-pentenol, cyclopentenol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentenol, 2-methyl-2-pentenol, 2-methyl-3-pentenol, 3-methyl-1-pentenol, 3-methyl-2-pentenol, 3-methyl-3-pentenol, 4-methyl-1-pentenol, 4-methyl-2-pentenol, 4-methyl-3-pentenol, cyclohexanol, and the like.

The protective layer composition may further include a fluorine-based compound surfactant, a leveling agent, and the like as an additive, as needed.

A patterning method according to an embodiment includes forming a photoresist layer on a substrate, forming a protective layer of a protective layer composition according to an embodiment of this disclosure on the photoresist layer, and forming a pattern through liquid immersion lithography.

For example, a photoresist layer of about 100 to about 500 nm may be formed by coating an upper portion of a substrate with a photosensitive resin composition, and drying the resultant substrate on a hot plate at a temperature of about 90 to about 130° C. for about 50 to about 90 seconds. A protective layer of about 20 to about 100 nm may be formed by coating the upper surface of the photoresist layer with a protective layer composition prepared according to an embodiment and drying the resultant substrate on a hot plate at a temperature of about 90 to about 130° C. for about 50 to about 90 seconds. The photoresist layer with the protective layer formed therein is exposed and developed through liquid immersion lithography to thereby develop a pattern.

Hereinafter, embodiments are described in more detail with reference to examples. The following Examples and Comparative Example are provided in order to set forth particular details of one or more embodiments. However, it will be understood that the embodiments are not limited to the particular details described. Further, the Comparative Example is set forth to highlight certain characteristics of certain embodiments, and is not to be construed as either limiting the scope of the invention as exemplified in the Examples or as necessarily being outside the scope of the invention in every respect.

### Synthesis of Monomer

### Synthesis Example

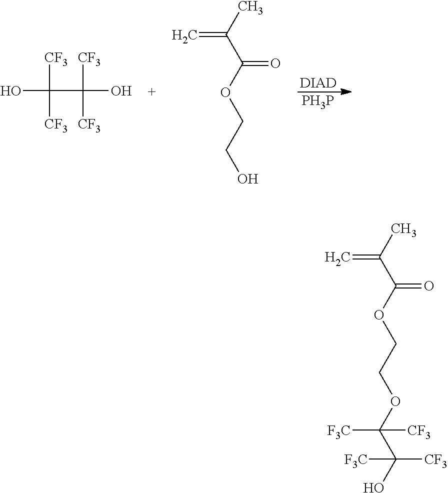

About 20 g (59.86 mmol) of hexafluoro-2,3-bis(trifluoromethyl)-2,3-butanediol(perfluoropinacol), about 7.79 g (59.86 mmol) of 2-hydroxyethylmethacrylate, and about 18.84 g (71.84 mmol) of triphenylphosphine (PH3P) were mixed in about 110 ml of diethylether and agitated in a nitrogen atmosphere. The mixture was agitated for about 30 minutes, and then the temperature of the mixture was brought down to about 0° C. and a mixture of about 14.52 g (71.84 mmol) of diisopropylazodicarboxylate (DIAD) and about 35 ml of diethylether was slowly dripped thereto for about 2 hours. Subsequently, the resultant solution was agitated at room temperature for about 24 hours and the mixture was concentrated. The concentrated mixture was dissolved in dichloromethane and a synthesized material was isolated through column chromatography using silica gel. About 15.2 g of 2-(2-hydroxy-1,1,2,2-tetra(trifluoromethyl)) oxyethylmethacrylate (Ma) (hereinafter referred to as a monomer “Cheil overcoat fluorine polymer (COFP)”) represented by Chemical Formula 1-1 below was synthesized through reduced pressure distillation (yield: 57%).

¹H-NMR (acetone-d6): δ1.90 (3H, t), 4.36 (4H, m), 5.63 (1H, t), 6.09 (1H, t), 8.34 (1H, s).

¹⁹F-NMR (acetone-d6): δ-70.12 (6F, m), −65.38 (6F, m).

Boiling point: 58 to 60° C., 30 mTorr.

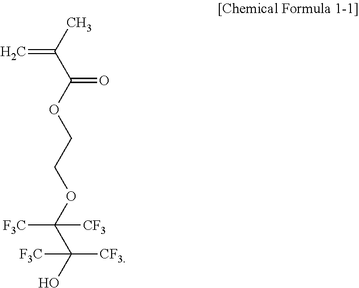

### Polymerization

### Preparation Examples 1 to 16

Monomers of Preparation Examples 1 to 16 in the following Table 1 were measured in the described mol % ratios and put into a beaker individually so that the total monomer amount became about 50 g, and then dissolved in about 100 g of isopropyl alcohol (IPA) solvent, which was twice the total weight of the monomer. About 4.10 g of V601 (dimethyl-2,2′-azobis (2-methylpropionate)), which is a polymerization initiator produced by Wako Chemicals, Inc., was put into the solution and exposed for about 30 minutes in a nitrogen atmosphere to thereby prepare a monomer solution.

About 50 g of isopropyl alcohol was put into a 500-ml 3-necked jacketed reactor equipped with a thermometer and a dropping funnel, and exposed for about 30 minutes in the nitrogen atmosphere. Subsequently, the temperature of the jacketed reactor was raised to about 80° C. and agitation was performed using a magnet agitator, and the monomer solution was injected at a uniform flow rate for about 4 hours or more by using a syringe pump. The injected monomer solution was agitated for about 2 hours after the injection ended.

After a reaction was ended, a polymer solution was prepared by agitating the solution at a temperature of about 25° C. or lower for about 30 minutes.

The polymer solution was transferred to a 2-L round bottom flask and the solvent was distilled under a reduced pressure. About 150 g of methanol was put into the reactant to dilute the reactant, and about 600 g of n-hexane was added thereto and agitated for about 3 hours. The reactant was transferred to a 2-L separatory funnel, and then among the reactants separated into the upper and lower portions in the separatory funnel, the lower portion was transferred into a 2-L round bottom flask and the remaining solvent was distilled under a reduced pressure. A reactant acquired from the reduced pressure distillation went through the extraction and the reduced pressure distillation twice more. Polymers of Preparation Examples 1 to 16 having a yield of about 80 to 95% were acquired by drying a resultant precipitation in a vacuum oven at about 60° C. for about 24 hours or more.

The weight average molecular weights of the polymers were measured using gel permeation chromatography (GPC) equipment, produced by Waters Corporation, and are presented in the following Table 1.

TABLE 1

| Preparation | COFP* | M2 | M-TMS | MAA | F2 | HFPMA | Weight average |
|---|---|---|---|---|---|---|---|
| Example | [mol %] | [mol %] | [mol %] | [mol %] | [mol %] | [mol %] | molecular weight |
| 1 | 100 | — | — | — | — | — | 22,400 |
| 2 | 97 | 3 | — | — | — | — | 6,200 |
| 3 | 95 | 5 | — | — | — | — | 14,800 |
| 4 | 97 | — | 3 | — | — | — | 4,900 |
| 5 | 97 | — | 3 | — | — | — | 21,200 |
| 6 | 95 | — | 5 | — | — | — | 20,400 |
| 7 | 95 | — | 5 | — | — | — | 21,500 |
| 8 | 93 | — | 7 | — | — | — | 15,200 |
| 9 | 97 | — | — | 3 | — | — | 4,900 |
| 10 | 97 | — | — | 3 | — | — | 15,300 |
| 11 | 95 | — | — | 5 | — | — | 14,200 |
| 12 | 97 | — | — | — | 3 | — | 19,300 |
| 13 | 95 | — | — | — | 5 | — | 16,400 |
| 14 | 90 | — | 5 | 5 | — | — | 10,500 |
| 15 | 90 | — | 5 | 5 | — | — | 14,700 |
| 16 | — | — | — | — | 5 | 95 | 10,500 |

*COFP, M2, M-TMS, MAA, F2, and HFPMA are as described below.

In Table 1, COFP is a monomer prepared according to Synthesis Example 1, and is represented by Chemical Formula 1-1.

In Table 1, M2 is a monomer produced by Gelest, Inc., U.S.A., and is represented by the following Chemical Formula 2-4:

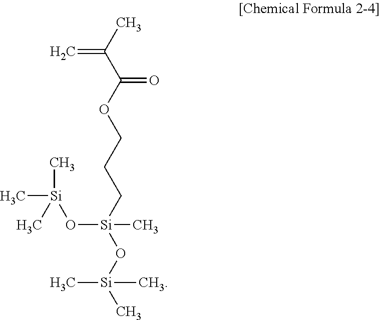

In Table 1, M-TMS is a monomer produced by Gelest, Inc., U.S.A., and is represented by the following Chemical Formula 2-2:

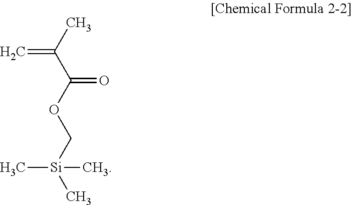

In Table 1, MAA is a monomer produced by Junsei Chemical Co., Ltd., Japan, and is represented by the following Chemical Formula 6-1:

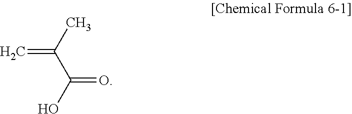

In Table 1, F2 is a monomer produced by TCI Co., Ltd., Japan, and is represented by the following Chemical Formula 6-3:

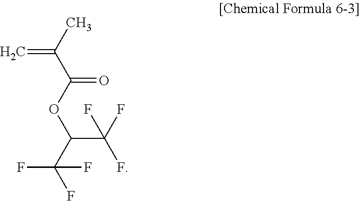

In Table 1, HFPMA is a monomer produced by Central Glass Co., Ltd., Japan, and is represented by the following Chemical Formula 7:

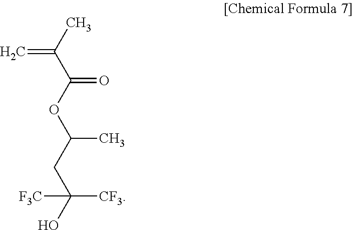

### Preparation of Protective Layer Composition

### Examples 1 to 15

Protective layer compositions of Examples 1 to 15 were prepared by putting about 10 g of each of the polymers prepared according to Preparation Examples 1 to 15 into about 390 g of 4-methyl-2-pentenol:isoamylether (60:40 weight ratio) and agitating the mixture for about 4 hours, individually.

### Comparative Example 1

A protective layer composition of Comparative Example 1 was prepared by putting about 10 g of the polymer of Preparation Example 16 into about 390 g of 4-methyl-2-pentenol:isoamylether (60:40 weight ratio) and agitating the mixture for about 4 hours.

[Evaluation of Physical Properties 1: Measurement of Dissolution Rate]

The dissolution rates (DR) of the protective layer compositions prepared according to Examples 1 to 15 and Comparative Example 1 were measured using a device RDA-760, produced by Litho Tech Japan Corporation.

First, a bare silicon wafer was coated with each of the protective layer compositions of Examples 1 to 15 and Comparative Example 1 at a thickness of about 400 to 450 Å, baked at about 110° C./60 sec, and cooled to room temperature in a span of about 60 seconds to thereby fabricate a wafer with a protective layer formed therein.

The thickness of the wafer with a protective layer was measured with a thickness measuring device produced by K-MAC Company, the wafer with a protective layer was put into the RDA-760 containing 2.38 wt % tetramethyl ammonium hydroxide (TMAH), produced by AZ EM Company, and the extent of development based on time was measured. The thickness of the wafer was measured again after the measurement of the development extent, and the difference between the initial thickness and the later thickness was calculated to thereby determine the dissolution rates (DR) of each protective layer developed per hour. The measurement results are as shown in the following Table 2.

[Evaluation of Physical Property 2: Measurement of Contact Angle]

The contact angles of the protective layer compositions prepared according to Examples 1 to 15 and Comparative Example 1 were measured using a DSA-100, produced by KRÜSS GmbH.

First, a bare silicon wafer was coated with each of the protective layer compositions prepared according to Examples 1 to 15 and Comparative Example 1 at a thickness of about 400 to 450 Å, baked at about 110° C./60 sec, and cooled to room temperature in a span of about 60 seconds to thereby fabricate a wafer with a protective layer formed thereon.

2-1. Static Contact Angle

The contact angle was measured by dropping about 45 microliter of deionized water (DIW) onto the wafer with a top coat layer and using the DSA-100 produced by KRÜSS GmbH. The measurement results are as shown in the following Table 2.

2-2. Dynamic Contact Angle

The receding contact angle and advancing contact angle were measured by dripping about 45 microliter of deionized water (DIW) onto the wafer with a protective layer and using the DSA-100 produced by KRÜSS GmbH while slanting the wafer at a speed of 1°/sec.

The difference between the advancing contact angle and the receding contact angle, which were measured in the above method, was calculated, and dynamic contact angle hysteresis was determined on the surface of the protective layer of each wafer. The measurement results are as shown in the following Table 2.

TABLE 2

| | | | Dynamic contact angle [°] | | |
|---|---|---|---|---|---|
| | Developing | Static contact | | advancing | |
| | rate | angle [°] | | contact | hys- |
| Example | [nm/s] | receding contact angle | | angle | teresis |
| 1 | 120.08 | 91.3 | 68 | 99.4 | 31.4 |
| 2 | 117.45 | 91.7 | 73.2 | 104.8 | 31.6 |
| 3 | 103.78 | 93 | 75.3 | 101.9 | 26.6 |
| 4 | 111.84 | 87.4 | 66.3 | 99.4 | 33.1 |
| 5 | 105.08 | 92.8 | 69.2 | 100.1 | 30.9 |
| 6 | 77.06 | 88.5 | 70.9 | 99.8 | 28.9 |
| 7 | 66.06 | 93.2 | 73.8 | 100.7 | 26.9 |
| 8 | 89.23 | 93 | 73.6 | 101.3 | 27.7 |
| 9 | 82.16 | 88.3 | 74.3 | 99.5 | 25.2 |
| 10 | 73.36 | 85.4 | 65 | 102 | 37 |
| 11 | 84.67 | 88 | 73.8 | 100.6 | 26.8 |
| 12 | 77.59 | 87.5 | 68.2 | 102.3 | 34.1 |
| 13 | 119.74 | 88.7 | 69.9 | 100.7 | 30.8 |
| 14 | 107.78 | 88 | 73.7 | 100.6 | 26.9 |
| 15 | 132.61 | 87.5 | 73.8 | 101.7 | 27.9 |
| Comparative | 52 | 87 | 66.3 | 98.8 | 32.5 |
| Example 1 | | | | | |

Referring to Table 2, the protective layer composition including a polymer polymerizing COFP monomers had better solubility than that of Comparative Example 1. Thus, the dissolution rates (DR) were fast and the hydrophobic properties were strong. Further, the static contact angle value was large. Also, when the dynamic contact angle was measured, the receding contact angle was generally higher than that of Comparative Example 1, and the advancing contact angle was generally lower than that of Comparative Example 1. Thus, the dynamic contact angle hysteresis value was smaller than that of Comparative Example 1. Since water was readily injected and drained to and from the surface of the protective layer prepared according to an embodiment of this disclosure, defects such as a water mark were not caused. Therefore, it was possible to predict improvement in productivity originating from the improved scanning speed during exposure.

[Evaluation of Physical Property 3: Pattern Shape]

First, a bottom anti-reflective coating (BARC) layer was formed on top of a silicon wafer.

A photoresist layer of about 200 nm was formed on top of the bottom anti-reflective coating layer by using JSAR-2629, which is an acrylate-based ArF photoresist composition produced by JSR Corporation, and pre-baked at about 100° C./60 sec.

A protective layer of about 40 nm was formed of the protective layer composition of Example 6 on top of the photoresist layer.

A wafer with the photoresist layer and the protective layer formed thereon was exposed using an ArF scanner NSR-S308F (NA 0.92, annular, sigma 0.92-0.72) produced by Nikon Corporation, and went through a post-exposure baking (PEB) at about 100° C./60 sec.

Subsequently, a 1:1.2 line-and-space (L/S) pattern of about 60 nm was formed using an ArF light source by cleaning the wafer with 2.38 wt % tetramethylammonium hydroxide (TMAH), which is an alkali development solution, and drying the wafer at about 110° C. in a span of about 60 seconds.

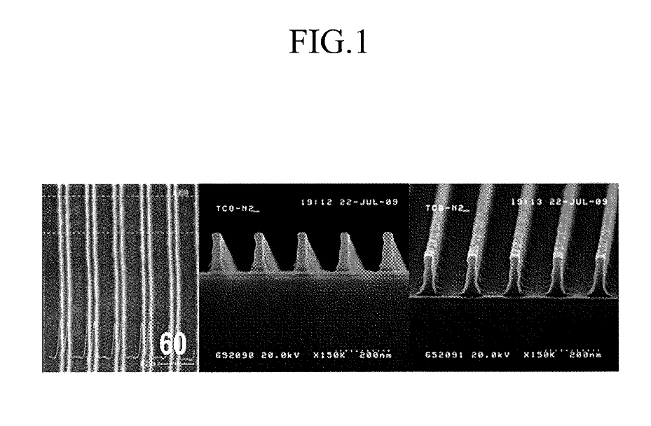

The pattern formed based on Example 6 was observed using a S-9380 scanning electron microscope (SEM), which is a CD-SEM produced by Hitachi Ltd., and S-4800, which is a FE-SEM produced by Hitachi Ltd., and the observation result is presented in FIG. 1.

It may be seen from FIG. 1 that the top portion of the photoresist is angularly close to a rectangular shape.

[Evaluation of Physical Property 4: Measurement of Process Margin]

First, an anti-reflective coating (BARC) layer was formed over a silicon wafer.

A photoresist layer of about 200 nm was formed of JSAR-2629, which is an acrylate-based ArF photoresist composition produced by JSR Corporation, on the bottom anti-reflection coating layer, and pre-baked at about 100° C./60 sec.

A protective layer of about 40 nm was formed on the protective layer composition of Example 6 on the photoresist layer.

A wafer with the photoresist layer and the protective layer formed therein was exposed using a device 1700i (NA 1.2), which is a scanner for liquid immersion exposure produced by ASML Corporation, and went through post-exposure baking at about 100° C./60 sec.

Subsequently, diverse patterns of about 50 nm were formed by cleaning the wafer with about 2.38 wt % TMAH, drying it at about 110° C. for about 60 seconds, and using an ArF light source.

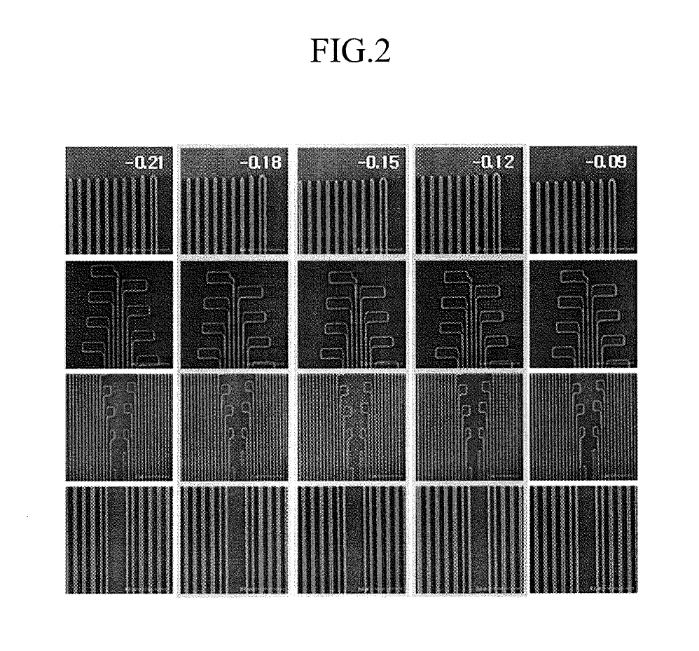

Among the patterns formed based on Example 6, a pattern of each depth of focus (DOF) at 30 mJ was observed using CD-SEM S-9380, which is produced by Hitachi Ltd., and the observation result is shown in FIG. 2.

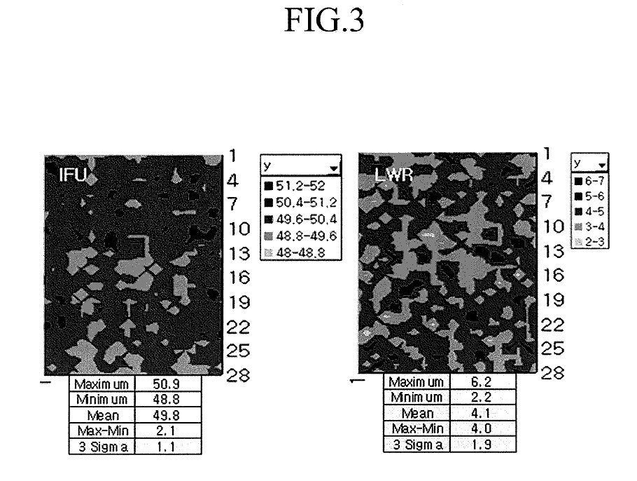

Also, the critical dimension (CD) deviation and line width roughness (LWR) of the pattern of the entire wafer were measured by using S-9380 produced by Hitachi Ltd., and the measurement result is presented in FIG. 3.

FIG. 2 indicates that the DOF margin at 30 mJ was 0.15, which means margins are secured in a wide region, and FIG. 3 shows that the CD deviation 3σ was 1.1 and LWR 3σ was 1.9, which are fine levels.

A polymer according to an embodiment may be highly hydrophobic, while increasing solubility for an alkali aqueous solution by having a plurality of fluorine substituents. Thus, the problem of a conventional polymer for a protective layer composition, which has an antinomic relationship between the hydrophobic property and the solubility, may be overcome by using a hydrophobic fluorine-based monomer and a carboxylic acid together.

In general, liquid immersion lithography may have a problem in that, since the photoresist layer directly contacts the liquid for immersion exposure such as water during the exposure, an acid generating component is eluted from the photoresist layer. If the amount of elution is large, the lens may be damaged and a desired pattern shape or a sufficient resolution may not be acquired. Also, in a case that water is used as the liquid for immersion exposure and a receding contact angle (RCA) of the water with respect to the photoresist layer is low, a water mark may remain due to poor water drainage during a high scan exposure. To resolve the problem, a method of using a particular kind of resin for liquid immersion lithography, or a method of using an additive, has been suggested. However, in such methods the receding contact angle between the photoresist layer and the water may not be sufficient, and the amount of the acid generating component eluted into the water may not be sufficiently reduced. To resolve the problems, a top coat layer may be introduced. The top coat layer may be a highly hydrophobic protective layer that may protect the photoresist layer from the water, it may be made of a material that may be easily removed by 2.38 wt % trimethyl ammonium hydroxide (TMAH), which is an alkali development solution, and it may transmit light. Polymers for a protective layer composition may introduce a hexafluoro alcohol (HFA) group and increase the solubility for the alkali development solution and the receding contact angle with respect to the water. However, when using such materials, the water mark may remain, and there may be a limitation in the scanning speed due to the low receding contact angle.

In contrast, as described above, embodiments may provide a hydrophobic polymer with a group having high acidity, and a protective layer composition for forming a protective layer having a high receding contact angle and high solubility with respect to an alkali development solution to thereby improve the after-image of a photoresist pattern profile.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A polymer, comprising:
a polymerized monomer, the monomer being represented by the following Chemical Formula 1: 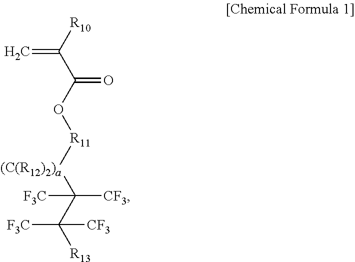
wherein, in Chemical Formula 1,
R₁₀ is selected from the group of hydrogen, fluorine, a C1 to C5 alkyl group, and a C1 to C5 fluoroalkyl group,
R₁₁ is a linear, branched, or cyclic C1 to C10 alkylene group where a part of carbon is replaced or not replaced with oxygen,
each R₁₂ is the same or different, and is selected from the group of hydrogen, a C1 to C5 alkyl group, and a C1 to C5 fluoroalkyl group,
a is an integer ranging from 0 to 10, and
R₁₃ is OH or SH.

2. The polymer as claimed in claim 1, wherein the monomer represented by Chemical Formula 1 is a monomer represented by the following Chemical Formula 1-1:

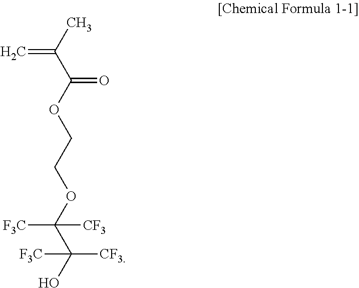

3. The polymer as claimed in claim 1, wherein the polymer has a weight average molecular weight of about 3,000 to about 50,000.

4. The polymer as claimed in claim 1, wherein the polymer is a copolymer of the monomer represented by Chemical Formula 1 and at least one monomer selected from the group of monomers represented by the following Chemical Formulae 2 to 6, 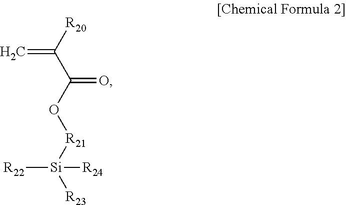
wherein, in Chemical Formula 2,
R₂₀ is selected from the group of hydrogen, fluorine, a C1 to C5 alkyl group, and a C1 to C5 fluoroalkyl group,
R₂₁ is a single bond or a linear, branched, or cyclic C1 to C10 alkylene group, and
R₂₂ to R₂₄ are the same or different, and are selected from the group of hydrogen, fluorine, a C1 to C10 alkyl group, a C1 to C10 fluoroalkyl group, and O(R₂₅),
wherein R₂₅ is selected from the group of hydrogen, fluorine, a C1 to C10 alkyl group, a C1 to C10 fluoroalkyl group, and Si(R₂₆)₃,
wherein R₂₆ is selected from the group of hydrogen, fluorine, a methyl group, and a trifluoromethyl group; 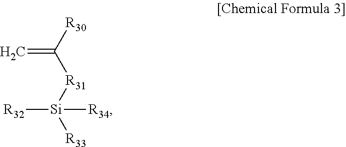
wherein, in Chemical Formula 3,
R₃₀ is selected from the group of hydrogen, fluorine, a C1 to C5 alkyl group, and a C1 to C5 fluoroalkyl group,
R₃₁ is a single bond or a linear, branched, or cyclic C1 to C10 alkylene group, and
R₃₂ to R₃₄ are the same or different, and are selected from the group of hydrogen, fluorine, a C1 to C10 alkyl group, a C1 to C10 fluoroalkyl group, and O(R₃₅),
wherein R₃₅ is selected from the group of hydrogen, fluorine, a C1 to C10 alkyl group, a C1 to C10 fluoroalkyl group, and Si(R₃₆)₃,
wherein R₃₆ is selected from the group of hydrogen, fluorine, a methyl group, and a trifluoromethyl group; 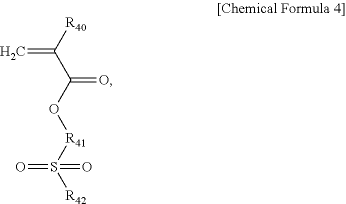
wherein, in Chemical Formula 4,
R₄₀ is selected from the group of hydrogen, fluorine, a C1 to C5 alkyl group, and a C1 to C5 fluoroalkyl group,
R₄₁ is a single bond or a linear, branched, or cyclic C1 to C10 alkylene group where a part of carbon is replaced or not replaced with nitrogen, and
R₄₂ is selected from the group of a C1 to C10 alkyl group, a C1 to C10 fluoroalkyl group and an OH group; 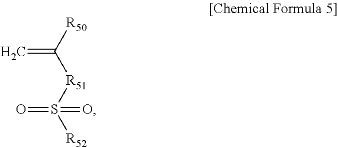
wherein, in Chemical Formula 5,
R₅₀ is selected from the group of hydrogen, fluorine, a C1 to C5 alkyl group, and a C1 to C5 fluoroalkyl group,
R₅₁ is a single bond or a linear, branched, or cyclic C1 to C10 alkylene group where a part of carbon is replaced or not replaced with nitrogen, and
R₅₂ is selected from the group of a C1 to C10 alkyl group, a C1 to C10 fluoroalkyl group, and an OH group; 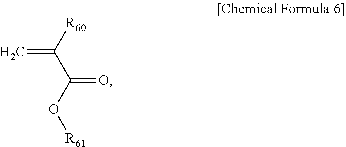
wherein, in Chemical Formula 6,
R₆₀ is selected from the group of hydrogen, fluorine, a C1 to C5 alkyl group, and a C1 to C5 fluoroalkyl group, and
R₆₁ is selected from the group of hydrogen, a C1 to C10 alkyl group, a C1 to C10 fluoroalkyl group, a C1 to C10 hydroxyalkyl group, and a C1 to C10 hydroxyalkyl group.

5. The polymer as claimed in claim 4, wherein the polymer is a copolymer of a monomer represented by Chemical Formula 1 and a monomer represented by Chemical Formula 2, the monomer represented by Chemical Formula 2 being selected from the group of monomers represented by the following Chemical Formulae 2-1 to 2-7:

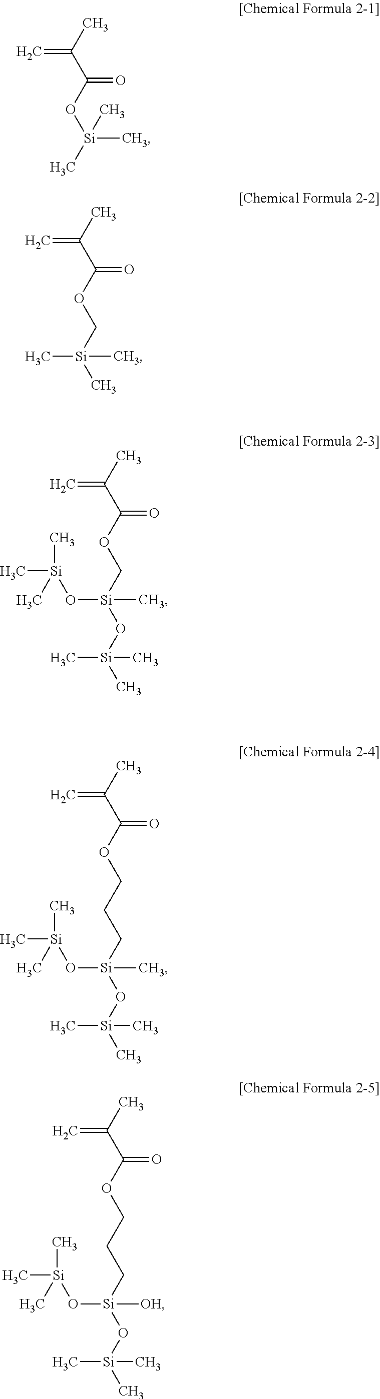

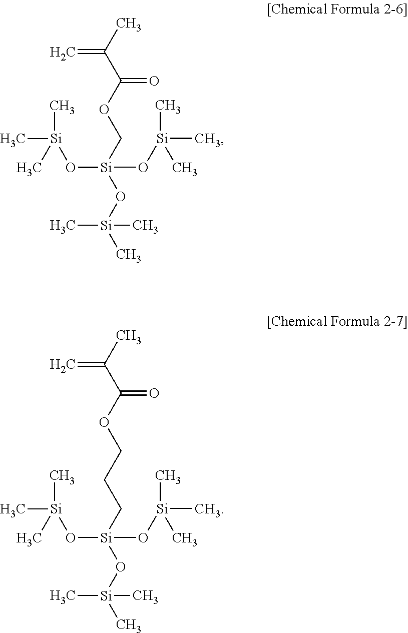

6. The polymer as claimed in claim 4, wherein the polymer is a copolymer of a monomer represented by Chemical Formula 1 and a monomer represented by Chemical Formula 3, the monomer represented by Chemical Formula 3 being represented by the following Chemical Formula 3-1:

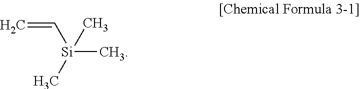

7. The polymer of claim 4, wherein the polymer is a copolymer of a monomer represented by Chemical Formula 1 and a monomer represented by Chemical Formula 4, the monomer represented by Chemical Formula 4 being selected from the group of monomers represented by the following Chemical Formulae 4-1 to 4-3:

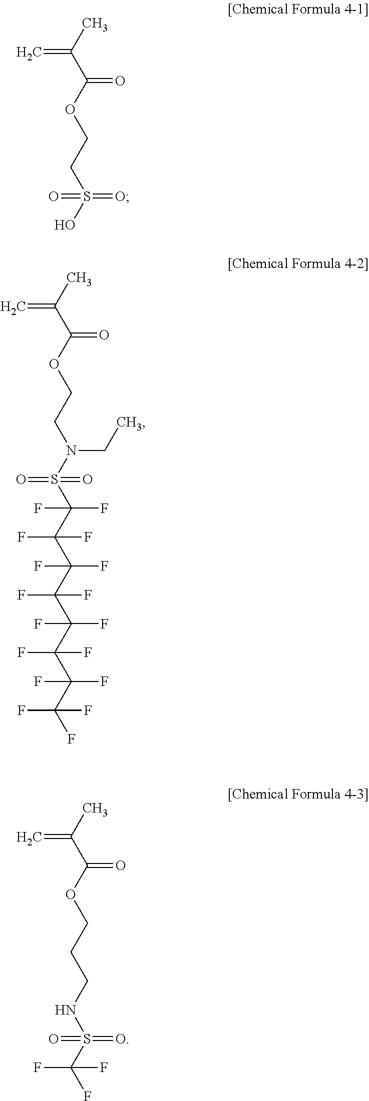

8. The polymer as claimed in claim 4, wherein the polymer is a copolymer of a monomer represented by Chemical Formula 1 and a monomer represented by Chemical Formula 5, the monomer represented by Chemical Formula 5 being selected from the group of monomers represented by the following Chemical Formulae 5-1 to 5-2:

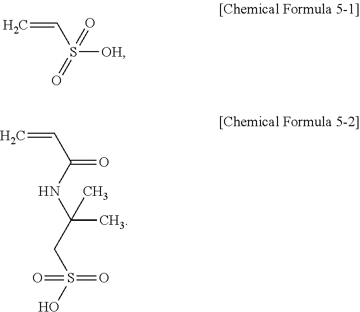

9. The polymer of claim 4, wherein the polymer is a copolymer of a monomer represented by Chemical Formula 1 and a monomer represented by Chemical Formula 6, the monomer represented by Chemical Formula 6 being a monomer selected from the group of monomers represented by the following Chemical Formulae 6-1 to 6-3:

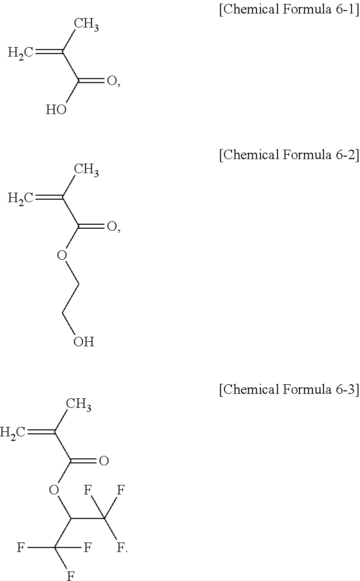

10. The polymer as claimed in claim 4, wherein the monomers represented by the above Chemical Formulae 2 to 6 are copolymerized in a ratio of about 1 to about 99 mol %, based on the entirety of the polymer.

11. A protective layer composition, comprising:
a polymer according to claim 1; and
a solvent.

12. A patterning method, comprising:
forming a photoresist layer on a substrate;
forming a protective layer using a composition according to claim 11 on the photoresist layer; and
forming a pattern through liquid immersion lithography using the photoresist layer having the protective layer thereon.
